(19) United States
(12) Patent Application Publication
(10) Pub. No.: US 2021/0249987 A1
(43) Pub. Date: Aug. 12, 2021

(54) Photovoltaic Facility and Method for Installing a Photovoltaic Facility

(71) Applicant: Total SE, Courbevoie (FR)

(72) Inventors: Frédéric Leroy, Vincennes (FR); Valérick Cassagne, Limours (FR)

(21) Appl. No.: 16/972,868

(22) PCT Filed: Jun. 6, 2019
(86) PCT No.: PCT/EP2019/064892

§ 371 Date: Dec. 7, 2020

(30) Foreign Application Priority Data
Jun. 8, 2018 (FR) 18/00581

(51) Int. Cl. H02S 20/10; H02S 40/34; H01L 31/0465; H01L 31/048

(52) U.S. Cl. CPC H02S 20/10; H01L 31/048; H01L 31/0465; H02S 40/34

(57) ABSTRACT

The invention concerns a photovoltaic facility (1) characterized in that it comprises a sealing tarpaulin (3) for at least partially covering a waste heap, and at least two flexible photovoltaic modules (4) comprising photovoltaic cells (5) made of monocrystalline or multicrystalline silicon, the at least two flexible photovoltaic modules (4) being connected together and secured on the sealing tarpaulin (3) by bonding.

The invention also concerns a method for installing such a photovoltaic facility (100) in which the at least two flexible photovoltaic modules (4) are bonded after having arranged the sealing tarpaulin (3) on the waste heap (2).

The present invention relates to a photovoltaic facility for a waste heap. The invention also relates to a method for installing a photovoltaic facility of this kind.

Some waste, such as waste heaps produced by mining operations, are stored in the form of mounds that can become very large and may be spread over large surface areas. These large surface areas thus dedicated to simply storing waste are of very little value.

Furthermore, these mounds are exposed to rain. The rainwater can infiltrate into the mound and thus affect the quality of the groundwater, due to the possible presence of contaminating elements in this waste. The infiltrated rainwater must therefore be treated before being reintroduced into the aquifers, which is expensive.

In order to avoid this, the mounds are covered by sealing tarpaulins, as is explained for example in the patent application WO2011/148139 in which the waste mound comprises in particular decomposing materials which may potentially contaminate the rainwater if said rainwater comes into contact with the accumulated detritus.

The slopes and the tarpaulins of the mounds make it possible to divert the rainwater in order to collect it, thus preventing it from infiltrating. The tarpaulins are furthermore equipped with flexible photovoltaic modules that are designed to convert the solar energy into electrical energy, thus creating value from the large surface areas of the mounds of waste. Photovoltaic modules of this kind, associated with tarpaulins, are disclosed in particular by the patent application WO2015/192126. However, the photovoltaic cells of said modules comprise silicon in the form of thin layers of amorphous silicon. The yield of said silicon structures, in terms of conversion of energy by the photovoltaic effect, is not very high, and relatively expensive. Moreover, depositing photovoltaic cells of this kind on flexible substrates intended to be flexurally curved may possibly lead to malfunction or breakage of said photovoltaic cells.

The present invention aims to provide a less expensive means, having an improved yield, for creating greater value from said large surface areas available, in the case of waste heaps made up of inert and non-decomposable materials.

To that end, the invention relates to a photovoltaic facility which is characterized in that it comprises a sealing tarpaulin which is intended for covering a waste heap, at least in part, and at least two flexible photovoltaic modules comprising photovoltaic cells based on monocrystalline or multi-crystalline silicon, the at least two flexible photovoltaic modules being interconnected and fixed to the sealing tarpaulin by means of adhesive bonding.

Thus, it will be understood that the sealing tarpaulin makes it possible to seal the waste heap, preventing infiltration of rainwater, while the flexible photovoltaic modules arranged on the tarpaulin make it possible to produce solar energy at a higher yield.

The photovoltaic facility thus benefits from the available slope of the waste heaps, generally raised to collect rainwater, for example of the order of 20° to 40°. This slope provides the flexible modules with a favorable orientation for successful production of solar electricity, and for natural washing by the rain drained by the slope.

The photovoltaic facility also benefits from large available waste storage surface areas that have been of little value hitherto.

The lightweight nature of the flexible photovoltaic modules furthermore makes it possible to not subject the sealing tarpaulin to mechanical stress.

Arranging the sealing tarpaulin on the surface prevents penetrating structures which may result in a risk of sealing faults and problems of quality of foundations in the heaps or the dumps.

The flexibility of the modules furthermore allows the modules to adjust to the topology of the terrain.

The monocrystalline or multi-crystalline structure of the silicon allows for a better yield than in the case of an amorphous silicon structure.

Furthermore, fixing the flexible modules by means of adhesive bonding is a low-aggression assembly process. Thus, the risk of damage to the sealing tarpaulin when fixing the modules is reduced. Moreover, fixing by adhesive bonding can be easily reversible, such that it is possible to remove one flexible module in order to replace it, if necessary, but without damaging the sealed nature of the tarpaulin, or even to re-attach a new module on the malfunctioning module.

The glue of the photovoltaic facility, interposed between the flexible photovoltaic modules and the sealing tarpaulin, comprises for example butyl. This type of glue does not creep once laid down.

According to an embodiment, the at least two flexible photovoltaic modules are formed, respectively, of a flexible laminate of photovoltaic cells comprising a layer of interconnected photovoltaic cells, a front and a rear encapsulation layer sandwiching the layer of photovoltaic cells.

According to a particular embodiment, the at least two flexible photovoltaic modules comprise, respectively, at least one stack of layers in the following arrangement:
a translucent layer located in front of the panel,
a layer of dry fiberglass fabric,
a layer of fiberglass fabric preimpregnated with epoxy resin,
a layer of photovoltaic cells,
a second layer of dry fiberglass fabric, and
a second layer of fiberglass fabric preimpregnated with epoxy resin,
a layer behind the panel.

The photovoltaic facility may comprise at least one junction box that is generally parallelepipedic in shape and comprises:
a contact face that is designed to be arranged in contact with a surface of the flexible photovoltaic module,
a connection face that is arranged so as to be perpendicular to the contact face and has at least one opening that is designed to allow at least one connection cable to pass through,
a fixing face comprising at least one fixing means for a chain return cable from the photovoltaic facility to the junction box, said fixing face being arranged so as to be perpendicular to the contact face and to the connection face.

The invention also relates to a method for installing a photovoltaic facility as described above, in which method the at least two flexible photovoltaic modules are adhesively bonded after the sealing tarpaulin has been deposited on the waste heap.

The installation of the photovoltaic facility on the waste heap is thus facilitated.

Indeed, fixing modules on the tarpaulin while said tarpaulin is already arranged on a waste heap is simplest to perform by means of adhesive bonding, in particular compared with fixing by welding, which would be more delicate to implement on-site.

In the same way, the installation of the sealing tarpaulin on the heap is simplest to perform without modules fixed in advance. Installing the modules later allows for less heavy sealing tarpaulins for transportation and installation, which tarpaulins can furthermore be folded during these operations.

Moreover, fixing the flexible modules after having deposited the tarpaulin allows for a more exact layout compared with the reality of the topology, and effective positioning of the tarpaulins, in particular preventing possible gaps.

Furthermore, flexible modules adhesively bonded after installation of the tarpaulin are subject to less mechanical stress, which makes the facility more robust.

Moreover, it is possible to limit the radius of curvature of the flexible photovoltaic modules adhesively bonded on the sealing tarpaulin to 20 cm.

Other features and advantages of the present invention will become clear upon reading the following description of an embodiment, given by way of non-limiting example and with reference to the accompanying drawings, in which:

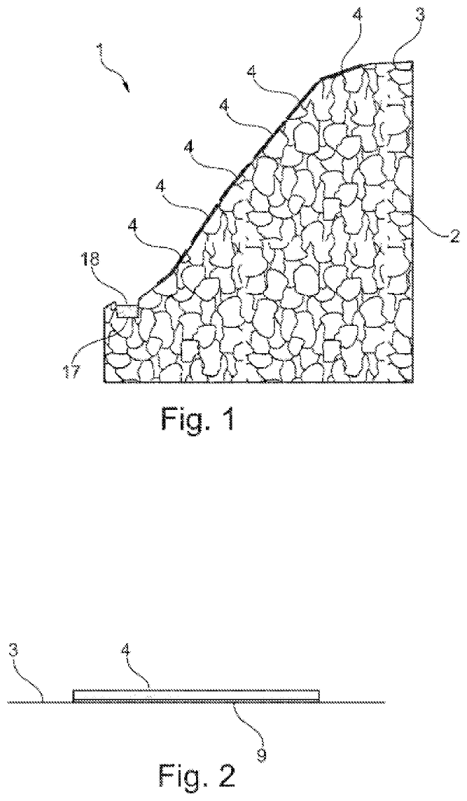

FIG. 1 is a schematic view of a photovoltaic facility arranged on a waste heap.

FIG. 2 is a schematic cross section of a portion of the photovoltaic facility.

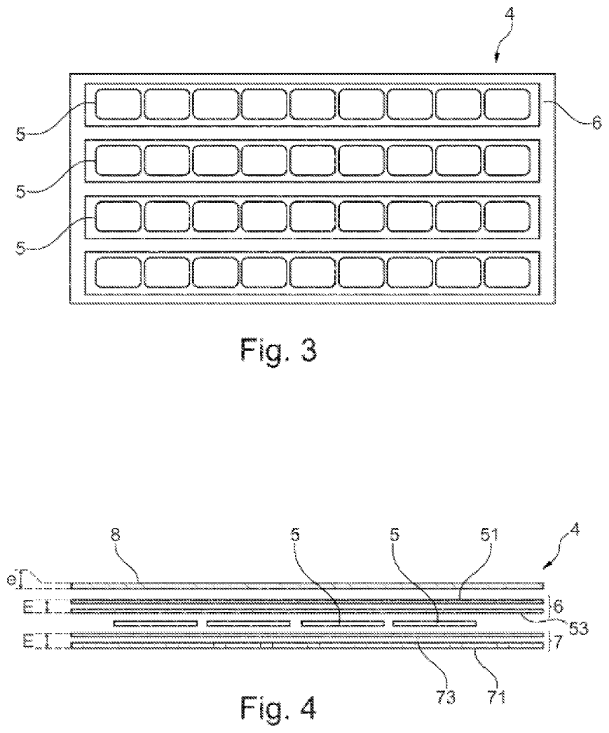

FIG. 3 is a schematic view from below of a flexible photovoltaic module.

FIG. 4 is a schematic cross section of a flexible photovoltaic module according to a first embodiment.

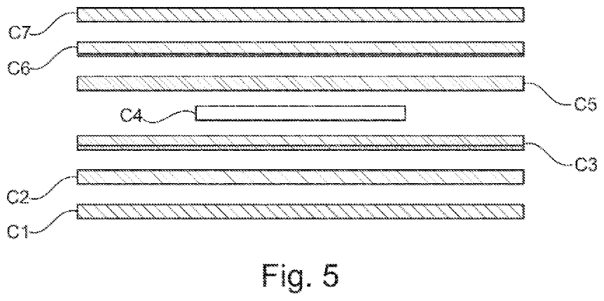

FIG. 5 is a schematic cross section of a flexible photovoltaic module according to a second embodiment.

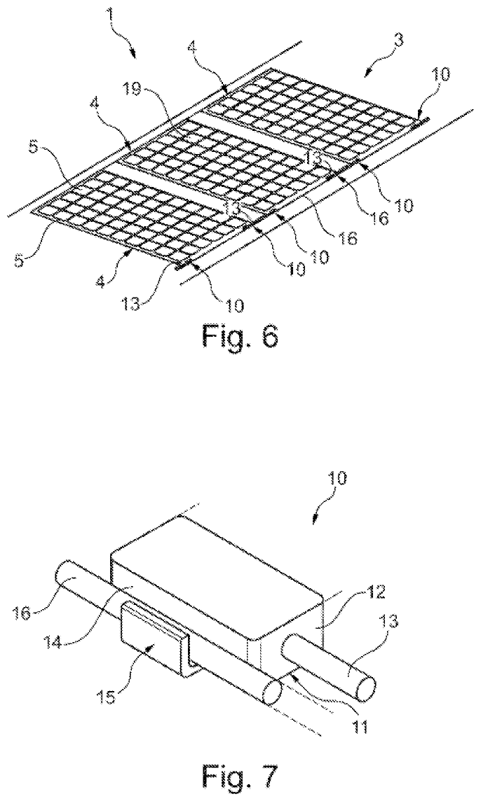

FIG. 6 is another schematic view of the photovoltaic facility.

FIG. 7 is a schematic view of a junction box according to an embodiment.

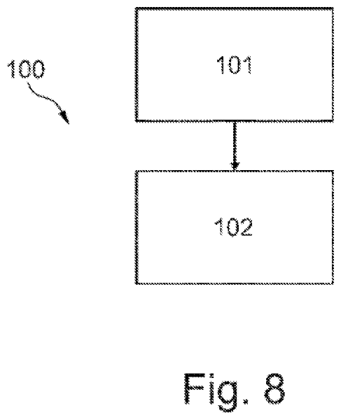

FIG. 8 is a schematic view of steps of a method for installing a photovoltaic facility.

In these figures, identical elements have been provided with the same reference signs.

The following embodiments are examples. Although the description refers to one or more embodiments, this does not necessarily mean that each reference relates to the same embodiment, or that the features apply merely to just one embodiment. Individual features of different embodiments can also be combined and/or interchanged in order to provide other embodiments.

In the following description “front layer” means the surface of the flexible module that is exposed first to the solar rays when the flexible module is installed. Similarly, in the following description “rear layer” means the layer opposite the front layer, i.e. the surface which the solar rays strike last during their travel through the installed module.

In the following description, “flexible” means the fact that, during application of a particular radius of curvature, the module does not crack. In the present invention, the module should withstand, without damage, a radius of curvature of 50 cm.

Furthermore, with reference to FIGS. 4 and 5, the various layers forming a flexible module are spaced apart from one another. This representation is provided only in order to better identify the various layers. In the installed state, the various layers shown are in contact with one another.

FIG. 1 shows a photovoltaic facility 1 arranged on a waste heap 2. The waste heap is made up mainly of inert solid waste, of mineral nature, such as waste originating from quarries.

The photovoltaic facility 1 comprises a sealing tarpaulin 3 which is intended to cover the waste heap 2 at least in part. The tarpaulin 3 can also cover a channel 17 that is formed for example at the foot of the heap 2, to drain the rainwater 18.

The sealing tarpaulin 3 is impermeable. It comprises, for example, one or more polymer(s), such as polyethylene (PE), bitumen, polyolefin (TPO), ethylene propylene diene monomer (EPDM), or polyvinyl chloride (PVC). These polymer materials can possibly be reinforced with fibers and/or multi-layers.

The photovoltaic facility 1 further comprises at least two flexible photovoltaic modules 4 (or flexible photovoltaic panels) comprising photovoltaic cells 5 based on monocrystalline or multi-crystalline silicon, the two flexible photovoltaic modules 4 being interconnected and fixed to the sealing tarpaulin 3 by means of adhesive bonding. The glue 9 interposed between the flexible photovoltaic modules 4 and the sealing tarpaulin 3 (FIG. 2) comprises for example butyl. This type of glue does not creep once laid down.

A flexible photovoltaic module 4 comprises photovoltaic cells 5, for example based on monocrystalline or multi-crystalline silicon, which are capable of converting the electromagnetic radiation of the sun into electrical energy, owing to the photovoltaic effect of the components of said photovoltaic cells.

According to an embodiment shown in FIGS. 3 and 4, the flexible photovoltaic modules 4 are formed, respectively, of a flexible laminate of photovoltaic cells 5 comprising a layer of interconnected photovoltaic cells 5, a front 6 and a rear 7 encapsulation layer sandwiching the layer of photovoltaic cells 5. The flexible laminate may be obtained for example by a conventional lamination method, i.e. by increasing the temperature of a stack of different layers forming the laminate, and then applying pressure to said stack for a predetermined duration, for example under vacuum or in an inert atmosphere.

With reference to FIG. 4, the front 6 and rear 7 encapsulation layers each comprise a fiberglass fabric 51, 71 and an encapsulation resin 53, 73. More particularly, the encapsulation resin 53, 73 is arranged between the layer of photovoltaic cells 5 and the fiberglass fabric 51, 71, in order to ensure the cohesion between the fiberglass fabric 51, 71 and the layer of photovoltaic cells 5. As a variant, each of the two front 6 and rear 7 layers can be formed of a single layer of impregnated fiberglass fabric.

At least the front encapsulation layer 6 is transparent, so as to allow solar rays to reach the layer of photovoltaic cells 5, in order to allow their conversion of photovoltaic energy into electrical energy.

When the flexible laminate is installed, the solar rays first penetrate the front encapsulation layer 6, then the layer of photovoltaic cells 5, and then, if they are not absorbed, the rear encapsulation layer 7.

The flexible module 4 can furthermore comprise an external film 8 made of a supple and transparent material, arranged on the front encapsulation layer 6. The external film makes it possible to increase the tightness of the laminate to humidity, and/or to provide a barrier to ultraviolet radiation and/or to limit the soiling of the module 4 due to the exposure of the flexible laminate 4 to climatic aggression and to dust.

The front 6 and rear 7 encapsulation layers each have, for example, a thickness E of between 0.05 mm and 3 mm. Such a thickness E of the front 6 and rear 7 encapsulation layers makes it possible to obtain a flexible laminate having a small thickness, which makes it possible in particular to reduce the costs associated with the transportation thereof, and the weight thereof.

According to a particular embodiment, the flexible photovoltaic modules 4 are designed, respectively, as described in the patent application WO2018/060611, the content of which is incorporated by reference in the present application.

The flexible photovoltaic module 4 (or photovoltaic panel, in the patent application WO2018/060611) comprises at least one stack of layers having the following arrangement (FIG. 5):
a translucent layer C1 located in front of the panel,
a layer of dry C2 fiberglass fabric,
a layer of fiberglass fabric C3 preimpregnated with epoxy resin,
a layer of photovoltaic cells C4,
a second layer of dry C5 fiberglass fabric, and
a second layer of fiberglass fabric C6 preimpregnated with epoxy resin,
a layer behind the panel C7.

The front layer C1 and/or the rear layer C7 may be formed of polymers.

The translucent layer C1 located in front of the panel, the layer of dry C2 fiberglass fabric, the layer of fiberglass fabric C3 preimpregnated with epoxy resin, form a front encapsulation layer 6. The layers of dry C5 fiberglass fabric, the layer of fiberglass fabric C6 preimpregnated with epoxy resin, and the rear layer of the panel C7 form a rear encapsulation layer 7.

Said module 4 can be obtained by a manufacturing method for a panel of photovoltaic cells described in the patent application WO2018/060611. The manufacturing method comprises a step of heating a stack of a plurality of layers comprising different materials, and a step of stacking, comprising the placement of the following layers:
a translucent front layer C1,
at least two layers C2, C5 of dry fiberglass fabric,
at least two layers C3, C6 of fiberglass fabric preimpregnated with epoxy resin,
a layer of photovoltaic cells C4,
a rear layer C7, the translucent front layer C1 and the layer of photovoltaic cells being separated by a layer C2, C5 of dry fiberglass fabric and a layer C3, C6 of fiberglass fabric preimpregnated with epoxy resin, the layer of photovoltaic cells C4 and the rear layer also being separated by a layer C2, C5 of dry fiberglass fabric and a layer C3, C6 of fiberglass fabric preimpregnated with epoxy resin.

In order to connect the photovoltaic facility 1 in particular to an inverter, the photovoltaic facility 1 may comprise at least one junction box 10 (FIGS. 6 and 7).

The junction box 10 is generally parallelepipedic in shape and comprises:
a contact face 11 that is designed to be arranged in contact with a surface of the flexible photovoltaic module 4,
a connection face 12 that is arranged so as to be perpendicular to the contact face 11 and comprises at least one opening that is designed to allow at least one connection cable 13 to pass through,
a fixing face 14 comprising at least one fixing means 15 for a chain return cable 16 from the photovoltaic facility 1 to the junction box 10, said fixing face 14 being arranged so as to be perpendicular to the contact face 11 and to the connection face 12.

The fixing means 15 may comprise one or more hold-back hooks of the chain return cable 16, such as resilient clips. The junction box 10 may be screwed, adhesively bonded, or clipped to the surface of the flexible photovoltaic module 4.

The junction boxes 10 may be aligned.

The photovoltaic facility 1 may comprise one or more junction boxes 10, for example two, per flexible photovoltaic module 4.

The use of a junction box 10 of this kind makes it possible to ensure the fixing of the chain return cable 16 and to guarantee an identical energy path produced for the outward and return between the flexible module 4 and the inverter. Furthermore, the presence of the fixing means 15 makes it possible to be free of complex, substantial, expensive cabling which may result in the presence of induction loops.

Thus, it will be understood that the sealing tarpaulin 3 makes it possible to seal the waste heap 2, preventing infiltration of rainwater, while the flexible photovoltaic modules 4 arranged on the tarpaulin 3 make it possible to produce solar energy.

The photovoltaic facility 1 thus benefits from the available slope of the waste heaps 2, generally raised to collect rainwater, for example of the order of 20° to 40°. This slope provides the flexible modules 4 with a favorable orientation for successful production of solar electricity, and for natural washing by the rain drained by the slope.

The photovoltaic facility 1 also benefits from large available waste storage surface areas that have been of little value hitherto.

The lightweight nature of the flexible photovoltaic modules 4 furthermore makes it possible to not subject the sealing tarpaulin 3 to mechanical stress.

Arranging the sealing tarpaulin 3 on the surface prevents penetrating structures which may result in a risk of sealing faults and problems of quality of foundations in the heaps or the dumps.

The flexibility of the modules 4 furthermore allows the modules 4 to adjust to the topology of the terrain.

Furthermore, fixing the flexible modules 4 by means of adhesive bonding is a low-aggression assembly process. Thus, the risk of damage to the sealing tarpaulin 3 when fixing the modules 4 is reduced. Moreover, fixing by adhesive bonding can be reversible, such that it is possible to remove one flexible module 4 in order to replace it, if necessary, but without damaging the sealed nature of the tarpaulin 3, or even to re-attach a new module on the malfunctioning module.

During the installation of the photovoltaic facility 1, it is furthermore possible to adhesively bond the flexible photovoltaic modules 4 onto the sealing tarpaulin 3 (FIG. 8, step 102 of the method for installing a photovoltaic facility 100) after it has been arranged on the waste heap 2 (FIG. 8, step 101).

Indeed, fixing modules 4 on the tarpaulin 3 while said tarpaulin is already arranged on a waste heap 2 is simplest to perform by means of adhesive bonding, in particular compared with fixing by welding, which would be more delicate to implement on-site.

In the same way, the installation of the sealing tarpaulin 3 on the heap 2 is simplest to perform without flexible modules 4 fixed in advance. Installing the modules later allows for less heavy sealing tarpaulins for transportation and installation, which tarpaulins can furthermore be folded during these operations.

Moreover, fixing the flexible modules 4 after having deposited the tarpaulin 3 allows for a more exact layout compared with the reality of the topology, and effective positioning of the tarpaulins 3, in particular preventing possible gaps.

Likewise, flexible modules 4 adhesively bonded after installation of the tarpaulin 3 are subject to less mechanical stress, which makes the photovoltaic facility 1 more robust.

Moreover, it is possible to limit the radius of curvature of the flexible photovoltaic modules 4 adhesively bonded on the sealing tarpaulin 3 arranged on the waste heap 2 to 20 cm, in order to increase the durability and the mechanical strength of the modules 4.

1. A photovoltaic facility, wherein the photovoltaic facility comprises a sealing tarpaulin which is intended for covering a waste heap, at least in part, and at least two flexible photovoltaic modules comprising photovoltaic cells based on monocrystalline or multi-crystalline silicon, the at least two flexible photovoltaic modules being interconnected and fixed to the sealing tarpaulin by means of adhesive bonding.

2. The photovoltaic facility according to claim 1, wherein the glue of the photovoltaic facility, interposed between the flexible photovoltaic modules and the sealing tarpaulin, comprises butyl.

3. The photovoltaic facility according to claim 1, wherein the at least two flexible photovoltaic modules are formed, respectively, of a flexible laminate of photovoltaic cells comprising a layer of interconnected photovoltaic cells, a front and a rear encapsulation layer sandwiching the layer of photovoltaic cells.

4. The photovoltaic facility according to claim 1, wherein the at least two flexible photovoltaic modules comprise, respectively, at least one stack of layers in the following arrangement:
a translucent layer located in front of the panel,
a layer of dry fiberglass fabric,
a layer of fiberglass fabric preimpregnated with epoxy resin,
a layer of photovoltaic cells,
a second layer of dry fiberglass fabric,
a second layer of fiberglass fabric preimpregnated with epoxy resin, and
a layer behind the panel.

5. The photovoltaic facility according to claim 1, further comprising at least one junction box that is generally parallelepipedic in shape and comprises:
a contact face that is designed to be arranged in contact with a surface of the flexible photovoltaic module,
a connection face that is arranged so as to be perpendicular to the contact face and comprises at least one opening that is designed to allow at least one connection cable to pass through,
a fixing face comprising at least one fixing means for a chain return cable from the photovoltaic facility to the junction box, said fixing face being arranged so as to be perpendicular to the contact face and to the connection face.

6. A method for installing a photovoltaic facility according to claim 1, wherein the at least two flexible photovoltaic modules are adhesively bonded after the sealing tarpaulin has been deposited on the waste heap.

7. The method for installing a photovoltaic facility according to claim 6, wherein the radius of curvature of the flexible photovoltaic modules adhesively bonded on the sealing tarpaulin is limited to 20 cm.
